(19) United States
(12) Patent Application Publication
(10) Pub. No.: US 2010/0052712 A1
(43) Pub. Date: Mar. 4, 2010

(54) TEST APPARATUS FOR TESTING CIRCUIT BOARD

(75) Inventor: Chun-Hung Chou, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/497,706

(22) Filed: Jul. 6, 2009

(30) Foreign Application Priority Data
Aug. 26, 2008 (CN) 200810304201.5

(51) Int. Cl. G01R 31/02

(52) U.S. Cl. 324/754

(57) ABSTRACT

The disclosure relates to a test apparatus for testing a circuit board. The circuit board includes a connector and a plurality of test points connected to the connector via a plurality of lines and the connector of the circuit board is connected to the plurality of lines via a plurality of corresponding signal pins. The test apparatus includes a circuit, a connector, a plurality of probes, and a tester. The circuit includes a plurality of test points and lines connecting to the test points correspondingly. The connector is coupled to the connector of the circuit board. The plurality of probes contact with the test points of the test apparatus. The tester sends test-signals to the connector of the circuit board via the lines correspondingly, receives test-information on the test points of the circuit board via the connectors, analyzes the test-information, and generates a test-result of the circuit board.

### BACKGROUND

1. Technical Field

The disclosure relates to a test apparatus for testing a circuit board and, more particularly, to a test apparatus for testing a high-density integrated circuit board.

2. Description of the Related Art

Generally, a circuit board is tested using a probe. The probe of a tester directly contacts each test point on the circuit board. However, the test points of the circuit board may be densely packed and irregularly arranged on the circuit board. Accordingly, it is difficult to accurately wield the test probe. Furthermore, because testing is performed manually, the process is often time intensive.

### BRIEF DESCRIPTION OF THE DRAWINGS

The components in the drawings are not necessarily drawn to scale, the emphasis instead being placed upon clearly illustrating the principles of the test apparatus for testing the circuit board. Moreover, in the drawings, like reference numerals designate corresponding parts throughout the several views.

FIG. 1 is a schematic diagram of a circuit board under test in accordance with an exemplary embodiment.

FIG. 2 is a schematic diagram of a test apparatus for testing the circuit board of FIG. 1, in accordance with an exemplary embodiment.

### DETAILED DESCRIPTION

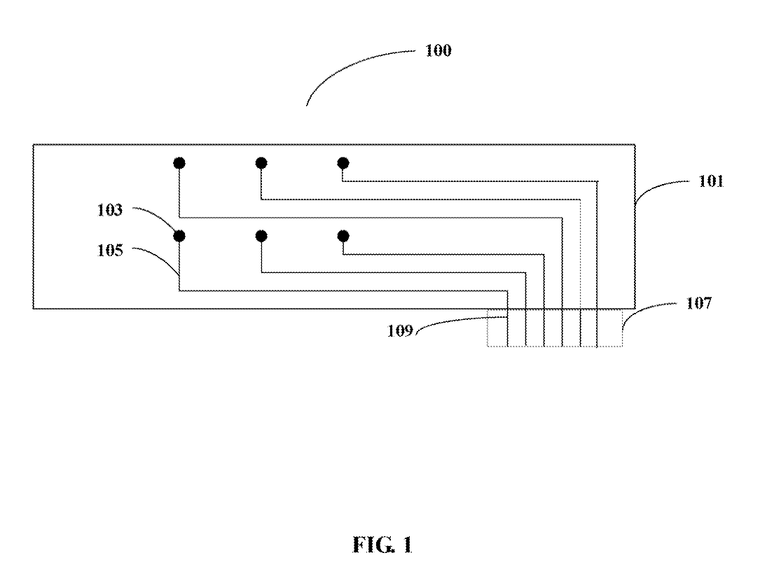

FIG. 1 is a schematic diagram of a circuit board 100 under test in accordance with an exemplary embodiment. The circuit board 100 under test includes a test circuit 101 and a connector 107. The test circuit 101 includes a plurality of test points 103 needing to be tested and corresponding lines 105 connecting the test points 103 to the connector 107. The connector 107 includes a plurality of signal pins 109 connected to the lines 105. The number of the signal pins 109 is equal to the number of the test points 103. In another exemplary embodiment, the test points 103 are divided into several groups. Accordingly, the circuit board 100 includes several connectors 107 in accordance with the number of the groups of test points 103.

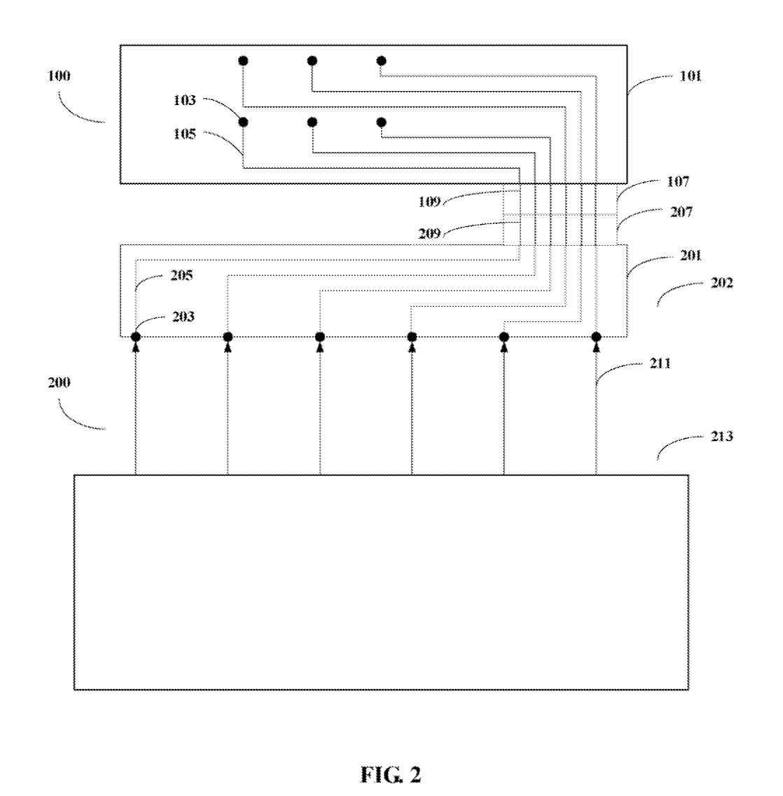

FIG. 2 is a schematic diagram of a test apparatus 200 for testing the circuit board 101 of FIG. 1. The test apparatus 200 includes an interconnecting circuit board 202 and a tester 213. The interconnecting circuit board 202 includes a circuit 201 and a connector 207. The circuit 201 includes a plurality of test points 203 and corresponding lines 205 connecting the test points 203 to the connector 207. The test points 203 may be arranged as desired. In the exemplary embodiment, the test points 203 are arranged in a line on the interconnecting circuit board 202. The connector 207 includes a plurality of signal pins 209 which are connected to the lines 205. The number of the signal pins 209 is equal to the number of the test points 203, and is also equal to the number of the signal pins 109 of the connector 107. The tester 213 includes a plurality of probes 211 which are configured for testing the test points 103 of the circuit 101. In another exemplary embodiment, the circuit board 100 includes several connectors 107 and the interconnecting circuit board 202 includes the same number of connectors 207 as the circuit board 100.

When utilizing the test apparatus 200 to test the circuit board 100, the connector 207 of the interconnecting circuit board 202 is coupled to the connector 107 of the circuit board 100, and the test points 103 are coupled to the test points 203 correspondingly. The probes 211 of the tester 213 contact the test points 203 and the tester 213 sends test-signals to the connector 207 via the lines 205. The connector 207 transmits the test-signals to the connector 107 and the connector 107 transmits the test-signals to the test points 103 via the lines 105. The circuit board 100 generates and feeds back test-information on the test points 103 to the connector 107 via the lines 105. The connector 107 transmits the test-information to the connector 207 and the connector forwards the test-information to the tester 213 via the lines 205. The tester 213 analyzes the test-information and generates a test-result of the circuit board 100. Because the test points 203 of the interconnecting circuit board 202 can be arranged as desired, it is easy to adjust configuration of the points that will be most efficient and convenient for testing a densely packed integrated circuit board, and avoid having to directly probe irregularly arranged test points of the circuit board.

It is understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A test apparatus for testing a circuit board which comprises a connector and a plurality of test points connected to the connector via a plurality of lines, the connector of the circuit board being connected to the plurality of lines via a plurality of corresponding signal pins, the test apparatus comprising:
a circuit, comprising a plurality of test points and lines connecting to the test points correspondingly;
a connector for being coupled to the connector of the circuit board;
a plurality of probes, for contacting with the test points of the test apparatus; and
a tester, for sending test-signals to the connector of the circuit board via the lines correspondingly, receiving test-information on the test points of the circuit board via the connectors, analyzing the test-information, and generating a test-result of the circuit board.

2. The test apparatus as recited in claim 1, wherein the test points are arranged in a line on the circuit.

3. The test apparatus as recited in claim 1, wherein the connector of the test apparatus comprises a plurality of signal pins, and the number of the signal pins is equal to the number of test points of the test apparatus.

4. The test apparatus as recited in claim 3, wherein the number of the signal pins of the connector of the test apparatus is the same as that of the signal pins of the connector of the circuit board.

5. The test apparatus as recited in claim 4, wherein the connector of the test apparatus is configured to connect to the connector of the circuit board via the signal pins.
